(19) United States
(12) Patent Application Publication
(10) Pub. No.: US 2011/0235388 A1
(43) Pub. Date: Sep. 29, 2011

(54) NONVOLATILE SEMICONDUCTOR STORAGE DEVICE

(75) Inventors: Hiroaki Nakano, Kanagawa (JP); Osamu Wada, Kanagawa (JP)

(73) Assignee: KABUSHIKI KAISHA TOSHIBA, Tokyo (JP)

(21) Appl. No.: 12/883,759

(22) Filed: Sep. 16, 2010

(30) Foreign Application Priority Data
Mar. 24, 2010 (JP) 2010-68601

(51) Int. Cl. G11C 17/16; G11C 29/00; G11C 17/00

(52) U.S. Cl. 365/96; 365/200; 365/94

(57) ABSTRACT

According to an embodiment of the invention, a nonvolatile semiconductor storage device includes a first memory cell and a second memory cell. A first fuse element in which data can be electrically written only once is provided in the first memory cell. A second fuse element in which data can be electrically written only once is provided in the second memory cell to repair a defect of the first memory cell.

### CROSS-REFERENCE TO RELATED APPLICATIONS

This application is based upon and claims the benefit of priority from the prior Japanese Patent Application No. 2010-68601, filed on Mar. 24, 2010; the entire contents of which are incorporated herein by reference.

### FIELD

The present invention relates generally to a nonvolatile semiconductor storage device.

### BACKGROUND

In some nonvolatile semiconductor storage devices in which data can be electrically written only once, a MOS transistor is used as a fuse element (H. Ito et. al., “Pure CMOS One-Time Programmable Memory using Gate-Ox Anti-Fuse”, Proceedings of the IEEE 2004 Custom Integrated Circuit Conference, pp. 469-472). In such a nonvolatile semiconductor storage device, when the information is stored in the fuse element, a high voltage exceeding a maximum rating is applied to a gate insulating film of the fuse element having a MOS structure, thereby breaking the insulating film. Information “0” is stored in the fuse element before the breakdown of the insulating film while information “1” is stored in the fuse element after the breakdown of the insulating film.

As to application of the nonvolatile semiconductor storage device, for example, the nonvolatile semiconductor storage device is used to retain defective element repair information on a semiconductor storage device such as a DRAM, an SRAM, and an EEPROM, information for setting states of various circuits constituting an LSI, and identification information on each chip.

In the application, the fuse element is programmed at a test stage in a production process, and there is a need to maintain the programmed state for a long term after product shipment. Because data may possibly be broken due to temporal change after being programmed depending on a producing condition or a programming condition of the fuse element, there is a strict demand for reliability of the fuse element.

In the use of the semiconductor storage device as a product, data stored in the fuse element is often automatically read and transferred to each circuit upon power-on. The fuse element is hardly repaired when having a defect, the product could be fatal even when only one bit is defective, and possibly a yield of the fuse element is directly linked to a yield of the product. Further, when the fuse element in which information is stored by breaking a gate oxide film is used, particularly retention of the reliability becomes strict because the gate oxide film is made thinner with the progress of finer design rules.

### BRIEF DESCRIPTION OF THE DRAWINGS

FIG. 1 is a block diagram illustrating a schematic configuration of a nonvolatile semiconductor storage device according to a first embodiment;

FIG. 2 is a block diagram illustrating a schematic configuration of a nonvolatile semiconductor storage device according to a second embodiment;

FIG. 3 is a block diagram illustrating a schematic configuration of an OTP memory of FIG. 2;

FIG. 4 is a circuit diagram illustrating a schematic configuration of a memory cell of FIG. 3;

FIG. 5 is a block diagram illustrating a schematic configuration of a nonvolatile semiconductor storage device according to a third embodiment;

FIG. 6 is a block diagram illustrating a schematic configuration of a nonvolatile semiconductor storage device according to a fourth embodiment;

FIG. 7 is a block diagram illustrating a schematic configuration of a nonvolatile semiconductor storage device according to a fifth embodiment;

FIG. 8 is a timing chart illustrating waveforms of respective units of the nonvolatile semiconductor storage device of FIG. 7;

FIG. 9 is a block diagram illustrating a schematic configuration of a nonvolatile semiconductor storage device according to a sixth embodiment;

FIG. 10 is a timing chart illustrating waveforms of respective units of the nonvolatile semiconductor storage device of FIG. 9;

FIG. 11 is a block diagram illustrating a schematic configuration of a nonvolatile semiconductor storage device according to a seventh embodiment;

FIG. 12 is a block diagram illustrating a schematic configuration of a fuse macro block that is formed using the nonvolatile semiconductor storage device of FIG. 11; and

FIG. 13 is a block diagram illustrating a schematic configuration of a nonvolatile semiconductor storage device according to an eighth embodiment.

### DETAILED DESCRIPTION

In general, according to embodiments, a first memory cell and a second memory cell are provided. The first memory cell includes a first fuse element in which data can be electrically written only once. The second memory cell includes a second fuse element in which data can be electrically written only once to repair a defect of the first memory cell.

A nonvolatile semiconductor storage device according to embodiments of the invention will be described below with reference to the drawings. However, the invention is not limited to the following embodiments.

### First Embodiment

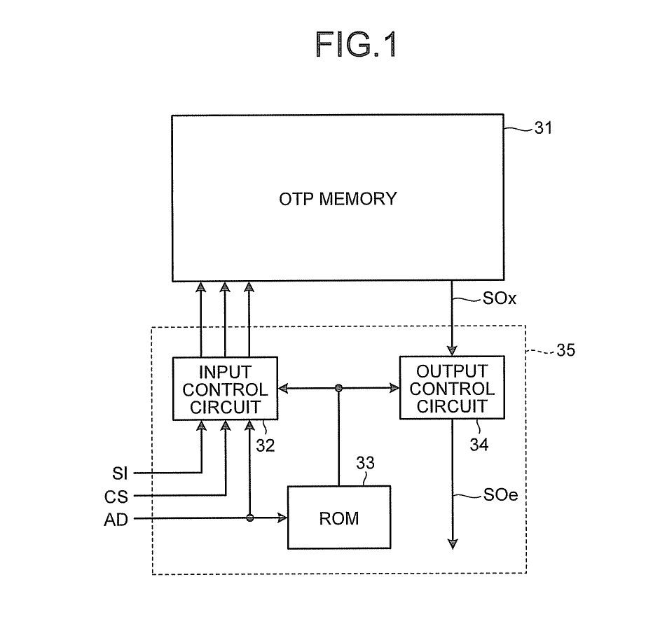

FIG. 1 is a block diagram illustrating a schematic configuration of a nonvolatile semiconductor storage device according to a first embodiment.

Referring to FIG. 1, the nonvolatile semiconductor storage device includes a one-time programmable (OTP) memory 31 and a repair controller 35.

In the OTP memory 31, data can be electrically written only once in a memory cell in which a fuse element is provided. As a method for electrically writing data only once in a memory cell, a method in which a high voltage exceeding a maximum rating is applied to a gate insulating film of the fuse element of a MOS structure such that the insulating film is broken, and information “0” is stored in the fuse element before the breakdown of the insulating film while information “1” is stored in the fuse element after the breakdown of the insulating film may be employed. Alternatively, a physical phenomenon such as electromigration may be generated by passing a current through a gate interconnection to break (cause a high-resistance state of) a silicide region constituting the interconnection or a part of the interconnection to store information.

The repair controller 35 can invert data read from a memory cell based on a result of reference to defective bit information indicating whether or not the memory cell provided in the OTP memory 31 is defective and output the inverted data. As the defective bit information, an address of the defective cell can be used.

The repair controller 35 includes an input control circuit 32, a ROM 33, and an output control circuit 34. The input control circuit 32 can perform write control of the OTP memory 31 based on program data SI, and control such that data is read from an address specified by an input address AD. A control signal CS can be used to specify read and write.

Defective bit information can be stored in the ROM 33. The defective bit information indicates whether or not the memory cell provided in the OTP memory 31 is defective. A flash memory may be provided instead of the ROM 33 so that the defective bit information on the memory cell in which the data is broken due to temporal change after being programmed may be stored. The output control circuit 34 can invert the data read from the memory cell based on the result of reference to the defective bit information and output the inverted data.

When data is written in the OTP memory 31, the input address AD is input to the input control circuit 32 and the ROM 33. When the input address AD is stored in the ROM 33, the input control circuit 32 is notified that the input address AD is stored in the ROM 33. Then, the input control circuit 32 can prohibit the data from being written in the memory cell specified by the input address AD.

On the other hand, when the input address AD is not stored in the ROM 33, the input control circuit 32 is notified that the input address AD is not stored in the ROM 33, and the data is written in the memory cell specified by the input address AD.

When the data is read from the OTP memory 31, the input address AD is input to the input control circuit 32 and the ROM 33. When the input address AD is stored in the ROM 33, the output control circuit 34 is notified that the input address AD is stored in the ROM 33. Then, the output control circuit 34 inverts data SOx read from the memory cell specified by the input address AD, and outputs the inverted data as output data SOe.

On the other hand, when the input address AD is not stored in the ROM 33, the output control circuit 34 is notified that the input address AD is not stored in the ROM 33. Then, the output control circuit 34 directly outputs the data SOx read from the memory cell specified by the input address AD as the output data SOe.

Because the data can be electrically written in a memory cell only once in the OTP memory 31, the memory cell can be determined to be defective when the information “1” is read from the memory cell while the information “0” is written in the memory cell. Similarly, the memory cell can be determined to be defective when the information “0” is read from the memory cell while the information “1” is written in the memory cell.

On the other hand, the memory cell can be determined to be nondefective when the information “0” is read from the memory cell while the information “0” is written in the memory cell. Similarly, the memory cell can be determined to be nondefective when the information “1” is read from the memory cell while the information “1” is written in the memory cell.

Accordingly, by storing the defective bit information in the ROM 33, directly outputting the data when the data is read from the nondefective cell, and outputting the inverted data when the data is read from the defective cell, the correct data can be read from the defective cell, and the defective cell can be repaired in units of bits without providing a repair cell.

### Second Embodiment

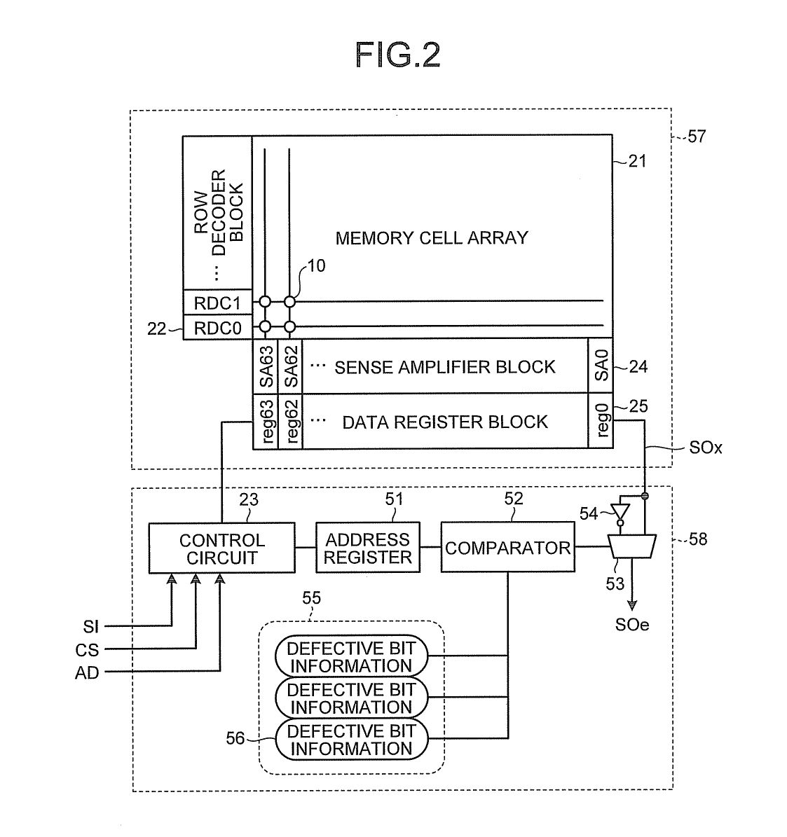

FIG. 2 is a block diagram illustrating a schematic configuration of a nonvolatile semiconductor storage device according to a second embodiment.

Referring to FIG. 2, the nonvolatile semiconductor storage device includes an OTP memory 57 and a repair controller 58.

The OTP memory 57 includes a memory cell array 21, a row decoder block 22, a control circuit 23, a sense amplifier block 24, and a data register block 25. In the memory cell array 21, memory cells 10 in which data can be electrically written only once are arrayed in the form of a matrix in a row direction and a column direction. In the row decoder block 22, row decoders RDC0, RDC1, . . . that select the memory cells 10 in the row direction are provided for respective rows. The control circuit 23 can perform control such that data is written in the address specified by the input address AD and such that data is read from the address specified by the input address AD.

In the sense amplifier block 24, sense amplifiers SA0 to SA63 are provided to detect whether data stored in the memory cells 10 is “0” or “1” in each column. In the data register block 25, data registers reg0 to reg63 are provided to retain the pieces of data detected by the sense amplifiers SA0 to SA63, respectively. In the example of FIG. 2, the 64 sense amplifiers SA0 to SA63 and the 64 data registers reg0 to reg63 are arranged. However, the invention is not limited to the configuration of FIG. 2.

The repair controller 58 includes an address register 51, a comparator 52, a selector 53, an inverter 54, and a defective bit information storage unit 55. The address register can store at what number of bit the data piece being read is in serially reading pieces of data. The comparator 52 can compare the read address and the defective bit information. The inverter 54 can invert the data read from the memory cell 10. Based on the comparison result of the comparator 52, the selector 53 can select the data read from the memory cell 10 or the inverted data of the data read from the memory cell 10. The defective bit information storage unit 55 can store defective bit information 56. For example, the address of the defective cell can be used as the defective bit information. A ROM or a flash memory can be used as the defective bit information storage unit 55.

When pieces of data are serially read from the OTP memory 57, the address register 51 stores at what number of bit the data piece being read is, and the comparator 52 compares the read address and the defective bit information.

When the read address and the defective bit information are matched with each other, output of the inverter 54 is selected, and the data obtained by inverting the data SOx read from the memory cell 10 is output as the output data SOe.

On the other hand, when the read address and the defective bit information are not matched with each other, output of the data register reg0 is selected, and the data SOx read from the memory cell 10 is directly output as the output data SOe.

Therefore, even if a plurality of defective cells exist, the defective cells can be repaired in units of bits without providing any repair cell, and the pieces of data can be read serially without interruption.

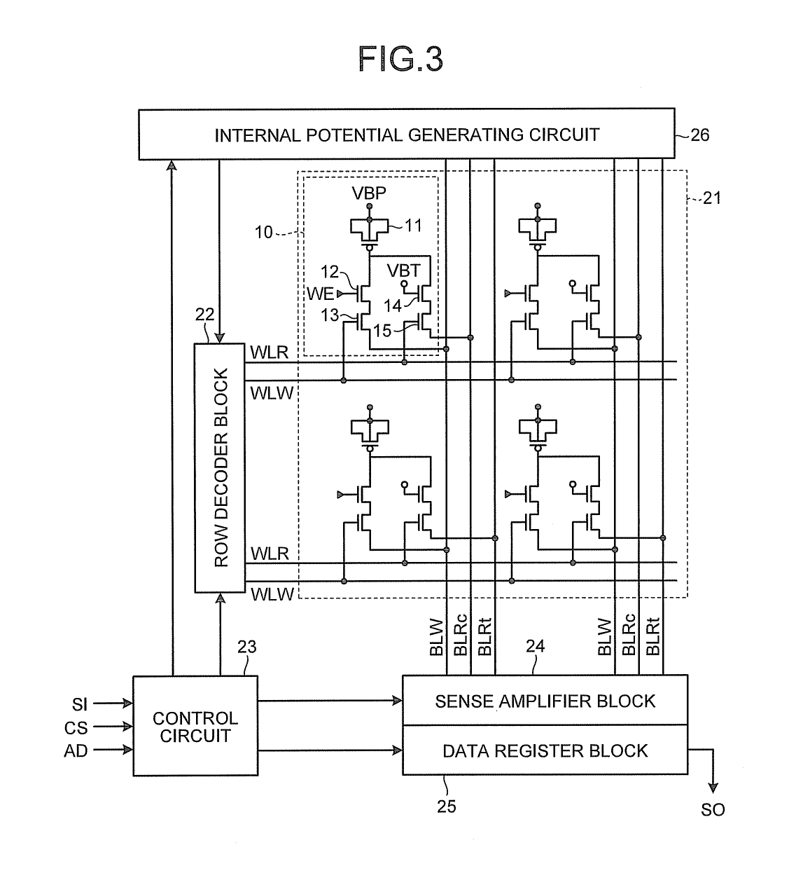

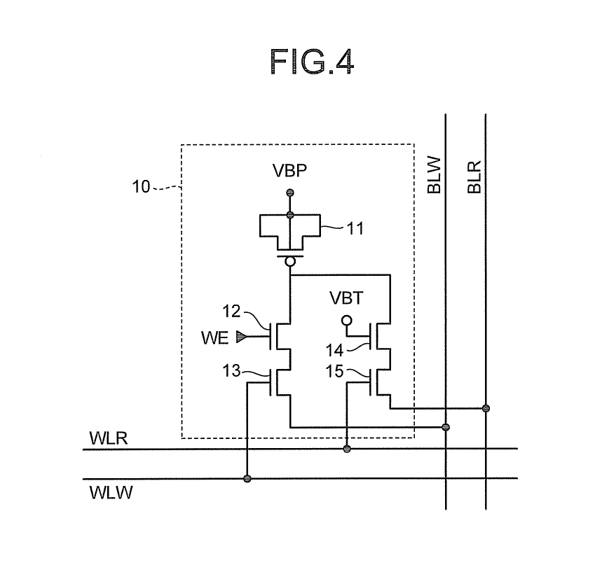

FIG. 3 is a block diagram illustrating a schematic configuration of the OTP memory of FIG. 2, and FIG. 4 is a circuit diagram illustrating a schematic configuration of the memory cell of FIG. 3.

Referring to FIGS. 3 and 4, the OTP memory 57 of FIG. 2 includes the memory cell array 21, the row decoder block 22, the control circuit 23, the sense amplifier block 24, the data register block 25, and an internal potential generating circuit 26. For example, the internal potential generating circuit 26 can generate a high voltage that can break the insulating film to the fuse element having the MOS structure.

In the memory cell array 21, the memory cells 10 in which data can be electrically written only once are arrayed in the form of a matrix in the row direction and the column direction. In the example of FIG. 3, the memory cells 10 of 2×2=4 bits are arrayed. However, the invention is not limited to the configuration of FIG. 3.

A write word line WLW and a read word line WLR are connected to a plurality of memory cells 10 constituting a row. Similarly, a pair of a write bit line BLW and a read bit line BLR (one of read bit lines BLRc and BLRt) is connected to a plurality of memory cells 10 constituting a column.

The memory cell 10 includes a fuse element 11, a write control transistor 12, a write transistor 13, a read barrier transistor 14, and a read transistor 15. In this case, a MOS transistor is provided in the fuse element 11, and data can be stored based on a change in conductivity caused by the breakdown of the gate insulating film of the MOS transistor.

One end of the fuse element 11 is connected to the source and the drain of the MOS transistor and a substrate, and the other end of the fuse element 11 is connected to the gate of the MOS transistor. The write transistor 13 and the write control transistor 12 are connected in series, and the read transistor 15 and the read barrier transistor 14 are connected in series.

One end of the fuse element 11 is connected to a memory cell power supply VBP. The other end of the fuse element 11 is connected to the drain of the write transistor 13 through the write control transistor 12, and to the drain of the read transistor 15 through the read barrier transistor 14. The write word line WLW is connected to the gate of the write transistor 13 in each of the memory cells 10 constituting the row. A write control signal WE is input to the gate of the write control transistor 12, and the write bit line BLW is connected to the source of the write control transistor 12 through the write transistor 13 in each of the memory cells 10 constituting the column. The read word line WLR is connected to the gate of the read transistor 15 in each of the memory cells 10 constituting the row. The power supply VET is connected to a gate terminal of the read barrier transistor 14, and the read bit line BLR is connected to the source of the read barrier transistor 14 through the read transistor 15 in each of the memory cells 10 constituting the column.

Write operation and read operation are performed to the fuse element 11 by the following procedure.

In the write operation, the write control signal WE is shifted from a low-level potential to a high-level potential, and input to the gate of the write control transistor 12. A potential at the memory cell power supply VBP is set to a high voltage of about 6 V. The write bit line BLW of the column including the selected cell is set to a low-level potential.

The low-level potential can be set to a ground potential (0 V) while the high-level potential can be set to a power supply potential VET (for example, 3 V). When the write control signal WE becomes the high-level potential, the write control transistor 12 is turned on.

When the address signal AD is input to the row decoder block 22, the potential at the write word line WLW of the row including the selected cell becomes the high-level potential.

When the potential at the write word line WLW of the row including the selected cell becomes the high-level potential, the write transistor 13 arranged in the row including the selected cell is turned on, the other end of the fuse element 11 is connected to the write bit line BLW of the selected column through the write control transistor 12 and the write transistor 13, thereby the high voltage of about 6 V is applied to electrodes at both ends of the gate insulating film of the fuse element 11.

When the state in which the high voltage is applied to the electrodes at both ends of the gate insulating film of the fuse element 11 is retained, the gate insulating film of the fuse element 11 of the selected cell is broken to reduce a resistance value of the fuse element 11, thereby information of one bit is written in the selected cell.

On the other hand, in the read operation, the write control signal WE is set to a low-level potential and input to the gate of the write control transistor 12. The potential at the memory cell power supply VBP is set to a low potential (for example, about 1 V) at which the fuse element 11 is not broken.

When the write control signal WE becomes the low-level potential, the write control transistor 12 is turned off. Then, when the address AD is input to the row decoder block 22, the potential at the read word line WLR of the row including the selected cell becomes the high-level potential.

When the potential at the read word line WLR of the selected row becomes the high-level potential, the read transistor 15 arranged in the row including the selected cell is turned on, and the other end of the fuse element 11 is connected to the read bit line BLR of the selected column through the read barrier transistor 14 and the read transistor 15, thereby the voltage read from the selected cell is applied to the read sense amplifier block 24.

The sense amplifier block 24 compares the voltage read from the selected cell to the reference potential, and determines whether the data stored in the selected cell is “0” or “1” based on a difference in read current obtained at this time.

### Third Embodiment

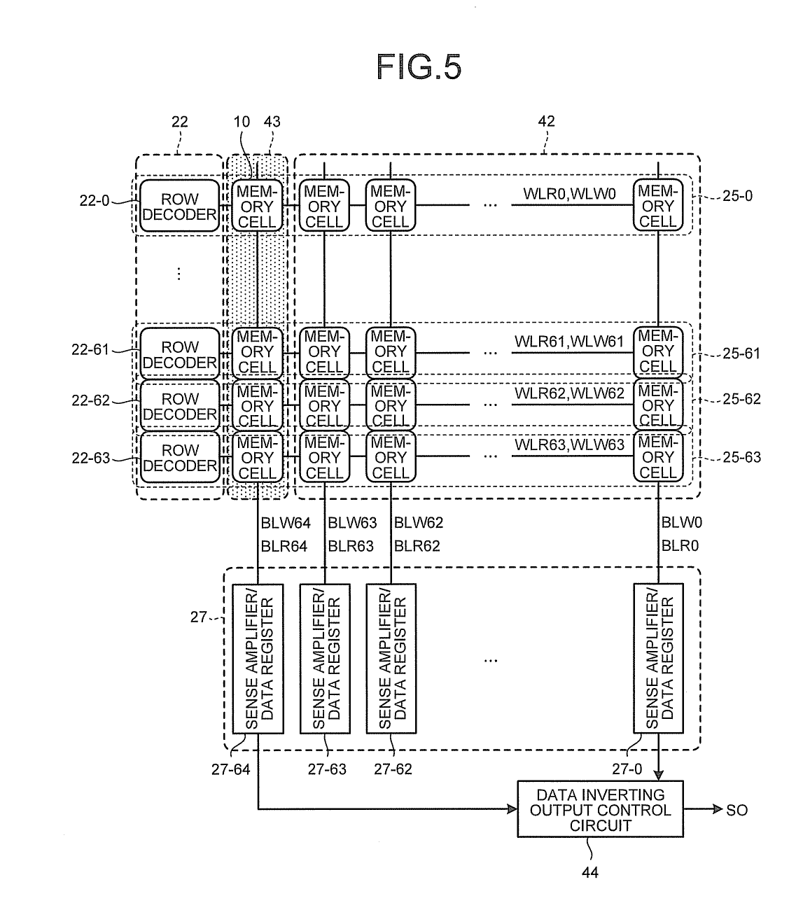

FIG. 5 is a block diagram illustrating a schematic configuration of a nonvolatile semiconductor storage device according to a third embodiment.

Referring to FIG. 5, the nonvolatile semiconductor storage device includes memory cells 10, a row decoder block 22, a sense amplifier/data register block 27, and a data inverting output control circuit 44.

In this case, the memory cells 10 are arrayed in the form of a matrix in a row direction and a column direction.

In the example of FIG. 5, the memory cells 10 of 65×64=4160 bits are arrayed. However, the invention is not limited to the configuration of FIG. 5.

The memory cells 10 located in the same row constitute each of row blocks 25-0 to 25-63, respectively. The memory cells 10 located in one column constitute a control information storage unit 43, and the memory cells 10 located in the residual columns constitute a data storage unit 42. In this case, the data storage unit 42 can store data therein in units of memory cells 10.

The control information storage unit 43 can store whether inverted data or non-inverted data is written in the memory cells 10 in the same row for each row. For example, the memory cell 10 of the row block 25-0 in the control information storage unit 43 can store whether the inverted data or non-inverted data is written in the memory cells 10 in the data storage unit 42 of the row block 25-0. Similarly, the memory cell 10 of the row block 25-63 in the information storage unit 43 can store whether the inverted data or non-inverted data is written in the memory cells 10 in the data storage unit 42 of the row block 25-63.

In the row decoder block 22, row decoders 22-0 to 22-63 that select the memory cells 10 in the row direction are provided for respective rows. The memory cells 10 in the same row are connected to the row decoders 22-0 to 22-63 through write word lines WLW0 to WLW63 and read word lines WLR0 to WLR63, respectively.

The sense amplifier/data register block 27 can constitute the sense amplifier block 24 and the data register block 25 of FIG. 3. In this case, the sense amplifier/data register block 27 includes sense amplifier/data registers 27-0 to 27-64 for respective columns. The memory cells 10 in the same column are connected to the sense amplifier/data registers 27-0 to 27-64 through the write bit lines BLW0 to BLW64 and read bit lines BLR0 to BLR64, respectively.

Based on a result of reference to the control information storage unit 43, the data inverting output control circuit 44 can invert pieces of data read from the memory cells 10 in the same row and output the inverted pieces of data.

When data is written in the memory cells 10 of the data storage unit 42, the number of memory cells 10 of the data storage unit 42 in which the pieces of data are written is calculated in each of the row blocks 25-0 to 25-63. When the number of memory cells 10 in which the pieces of data are written in each of the row blocks 25-0 to 25-63 exceeds a half of the number of memory cells 10 provided in any of the row blocks 25-0 to 25-63, the inverted pieces of data are written in the memory cells 10 for the relevant row blocks 25-0 to 25-63. That is, for the relevant row blocks 25-0 to 25-63, the information “0” remains written in a memory cell 10 that is instructed to write the information “1” therein, and the information “1” is written in a memory cell 10 that is instructed to write the information “0” therein.

For the row blocks 25-0 to 25-63 in which the inverted pieces of data are written in the memory cells 10, the information “1” is written in the memory cells 10 in the control information storage unit 43 belonging to the row blocks 25-0 to 25-63. For the relevant row blocks 25-0 to 25-63 in which the non-inverted pieces of data are written in the memory cells 10, the information “0” remains written in the memory cells 10 in the control information storage unit 43 belonging to the relevant row blocks 25-0 to 25-63.

When the pieces of data are read from the memory cells 10 in the data storage unit 42, one of the row blocks 25-0 to 25-63 is selected by the row decoders 22-0 to 22-63, and the pieces of data are read from the memory cells 10 of the selected one of the row blocks 25-0 to 25-63. The pieces of data read from the memory cells 10 in the data storage unit 42 of the selected one of the row blocks 25-0 to 25-63 are retained by the sense amplifier/data registers 27-0 to 27-63, respectively. The data read from the memory cell 10 in the control information storage unit 43 of the selected one of the row blocks 25-0 to 25-63 is retained by the sense amplifier/data register 27-64.

The pieces of data retained by the sense amplifier/data registers 27-0 to 27-64 are sent to the data inverting output control circuit 44. At this point, the data inverting output control circuit 44 operates in different ways depending on whether the data sent from the sense amplifier/data registers 27-64 is “0” or “1”. When the data “0” is sent from the sense amplifier/data register 27-64, the data inverting output control circuit 44 directly outputs the pieces of data sent from the sense amplifier/data registers 27-0 to 27-64 as output data SO. On the other hand, when the data “1” is sent from the sense amplifier/data register 27-64, the data inverting output control circuit 44 outputs the pieces of data obtained by inverting the pieces of data sent from the sense amplifier/data registers 27-0 to 27-64 are output as the output data SO.

At this point, when the number of memory cells 10 in which the pieces of data are written in each of the row blocks 25-0 to 25-63 exceeds a half of the number of memory cells 10 provided in any of the row blocks 25-0 to 25-63, the inverted pieces of data are written for the relevant row block 25-0 to 25-63, which allows the number of memory cells 10 in which the pieces of data are written to be decreased in each of the row block 25-0 to 25-63.

Therefore, the time necessary to write the data in the memory cells 10 can be shortened, and the decrease of yield caused by the programming defect can be prevented.

### Fourth Embodiment

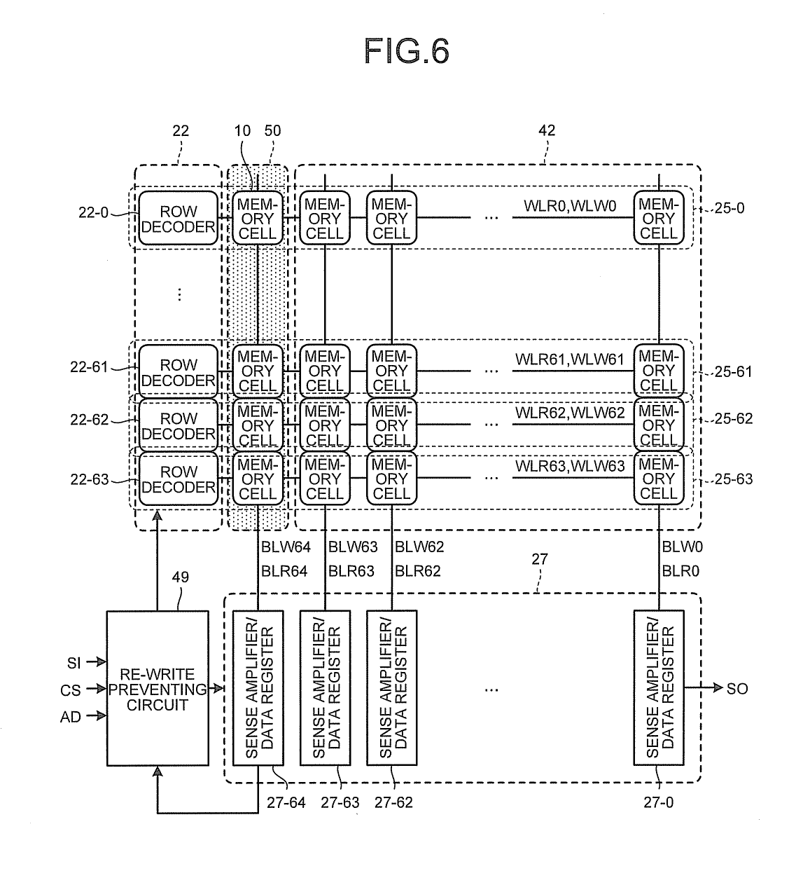

FIG. 6 is a block diagram illustrating a schematic configuration of a nonvolatile semiconductor storage device according to a fourth embodiment.

Referring to FIG. 6, the nonvolatile semiconductor storage device includes a control information storage unit 50 and a re-write preventing circuit 49 instead of the control information storage unit 43 and the data inverting output control circuit 44 of FIG. 5.

The control information storage unit 50 can store whether a memory cell 10 in which data is already written exists in each of the row blocks 25-0 to 25-63. For example, the memory cell 10 of the row block 25-0 in the control information storage unit 50 can store whether a memory cell 10 in which data is already written exists in the row block 25-0. Similarly, the memory cell 10 of the row block 25-63 in the control information storage unit 50 can store whether a memory cell 10 in which the data is already written exists in the row block 25-63.

Based on a result of reference to the control information storage unit 50, the re-write preventing circuit 49 can prevent data from being re-written in the memory cell 10 in which data is already written.

When data is written in the memory cells 10 in the data storage unit 42, for the row blocks 25-0 to 25-63 in which a memory cell 10 in which data is already written exists, the information “1” is written in the memory cell 10 in the control information storage unit 50 belonging to the row blocks 25-0 to 25-63. For the row blocks 25-0 to 25-63 in which the memory cell 10 in which data is already written does not exist, the information “0” remains written in the memory cell 10 in the control information storage unit 50 belonging to the row blocks 25-0 to 25-63.

When data is re-written in the memory cells 10 in the data storage unit 42, the sense amplifier/data register 27-64 retains the pieces of data read from the memory cells 10 in the control information storage unit 50 of one of the row blocks 25-0 to 25-63 selected based on the address AD.

The pieces of data retained by the sense amplifier/data registers 27-0 to 27-64 are sent to the re-write preventing circuit 49 to determine whether or not the pieces of data are “0” or “1”. When the data “0” is sent from the sense amplifier/data register 27-64, the re-write preventing circuit 49 permits the data to be written in the memory cell 10 specified by the address AD in the data storage unit 42.

On the other hand, when the data “1” is sent from the sense amplifier/data register 27-64, the re-write preventing circuit 49 prohibits the data from being written in the memory cell 10 specified by the address AD in the data storage unit 42. As to the method for prohibiting the data from being written in the memory cell 10, all the pieces of program data SI may be replaced by ‘0 ’ and transferred, or supply of the program voltage may be stopped.

Therefore, by adding the memory cells 10 of one column as the control information storage unit 50, it is possible to prevent data from being re-written in the memory cell 10 in which the data is already written and prevent data from being erroneously re-written.

The control information storage unit 43 is provided in the third embodiment of FIG. 5, and the control information storage unit 50 is provided in the fourth embodiment of FIG. 6. Alternatively, both the control information storage units 43 and 50 may be provided.

### Fifth Embodiment

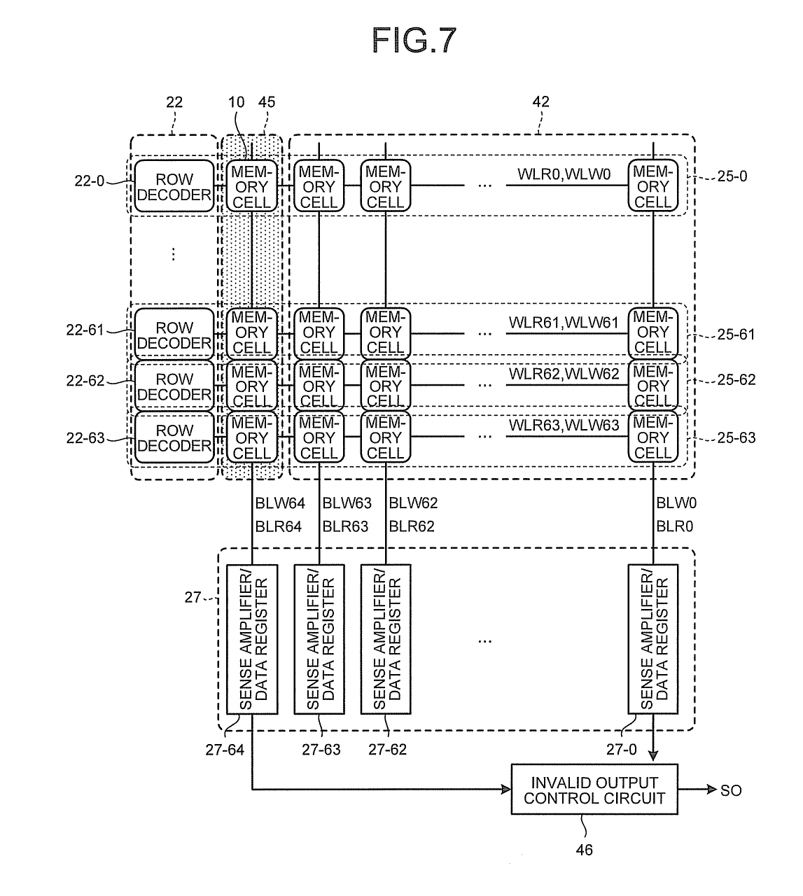

FIG. 7 is a block diagram illustrating a schematic configuration of a nonvolatile semiconductor storage device according to a fifth embodiment.

Referring to FIG. 7, the nonvolatile semiconductor storage device includes a control information storage unit 45 and an invalid output control circuit 46 instead of the control information storage unit 43 and the data inverting output control circuit 44 of FIG. 5.

The control information storage unit 45 can store whether a memory cell 10 having a small read margin or a memory cell 10 in which data is not correctly read is included in each of the row blocks 25-0 to 25-63. For example, the memory cell 10 in the control information storage unit 45 of the row block 25-0 can store whether a memory cell 10 having a small read margin or a memory cell 10 in which data is not correctly read is included in the row block 25-0. Similarly, the memory cell 10 in the control information storage unit 45 of the row block 25-63 can store whether a memory cell 10 having a small read margin or a memory cell 10 in which data is not correctly read is included in the row block 25-63.

Based on a result of reference to the control information storage unit 45, the invalid output control circuit 46 can invalidate the data read from the memory cells 10 in each of the row blocks 25-0 to 25-63.

When pieces of data are written in the memory cells 10 in the data storage unit 42, for the row blocks 25-0 to 25-63 in which a memory cell 10 having a small read margin or a memory cell 10 in which data is not correctly read exists, the information “1” is written in the memory cell 10 in the control information storage unit 45 belonging to the row blocks 25-0 to 25-63.

In addition, the pieces of data that should be written in the relevant row blocks 25-0 to 25-63 are written in the next row blocks 25-0 to 25-63, and the information “0” is written in the memory cell 10 of the control information storage unit 45 belonging to the relevant row blocks 25-0 to 25-63.

For example, it is assumed that a memory cell 10 having a small read margin or a memory cell 10 in which data is not correctly read exists in the row block 25-0, and that no memory cell 10 having a small read margin or no memory cell 10 in which data is not correctly read exists in the row blocks 25-1 to 25-63 other than the row block 25-0.

In such case, the information “1” is written in the memory cell 10 in the control information storage unit 45 belonging to the row block 25-0, the pieces of data that should be written in the row block 25-0 are written in the row block 25-1, and the information “0” is written in the memory cell 10 in the control information storage unit 45 belonging to the row block 25-1. Subsequently, the pieces of data that should be written in the row blocks 25-1 to 25-62 are written in the row blocks 25-2 to 25-63, respectively, that are shifted by one row, and the information “0” is written in the memory cells 10 in the control information storage unit 45 belonging to the row blocks 25-2 to 25-63.

Next, when the pieces of data are read from the memory cells 10 in the data storage unit 42, one of the row blocks 25-0 to 25-63 is selected by the row decoders 22-0 to 22-63, and the pieces of data are read from the memory cells 10 of the selected one of the row blocks 25-0 to 25-63. The pieces of data read from the memory cells 10 in the data storage unit 42 of the selected one of the row blocks 25-0 to 25-63 are retained by the sense amplifier/data registers 27-0 to 27-63, respectively. The data read from the memory cell 10 in the control information storage unit 45 of the selected one of the row blocks 25-0 to 25-63 is retained by the sense amplifier/data register 27-64. Further, the pieces of data retained by the sense amplifier/data registers 27-0 to 27-63 are output as output data SO.

On the other hand, the data retained by the sense amplifier/data register 27-64 is sent to the invalid output control circuit 46 to determine whether the data sent from the sense amplifier/data register 27-64 is “0” or “1”. When the data “1” is sent from the sense amplifier/data register 27-64, the invalid output control circuit 46 outputs a data valid signal DV indicating that the output data SO is invalid.

A data receiving side receives the data valid signal DV while receiving the output data SO. Therefore, a row including a defective cell can be replaced with a row that does not include any defective cell, and the defective cell can be thus repaired.

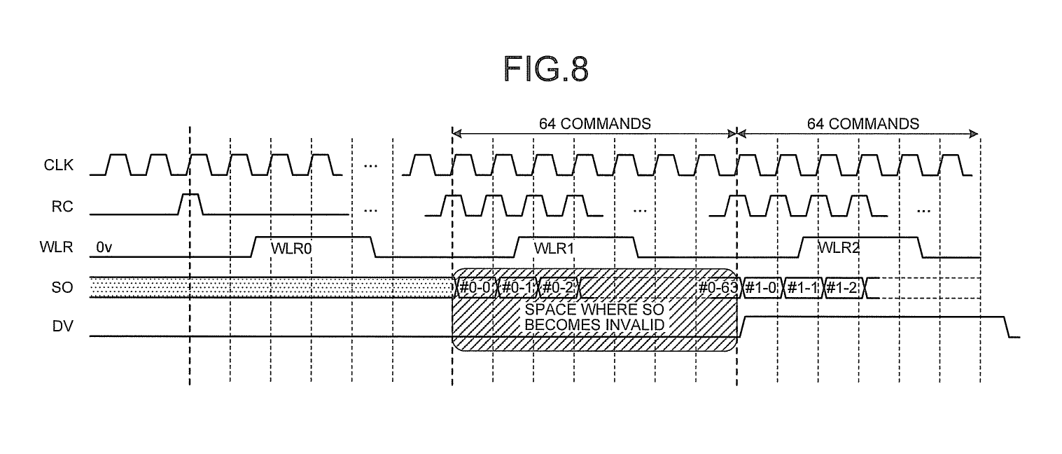

FIG. 8 is a timing chart illustrating waveforms of the respective units of the nonvolatile semiconductor storage device of FIG. 7.

In FIG. 8, it is assumed that a memory cell 10 having a small read margin or a memory cell 10 in which data is not correctly read exists in the row block 25-0 of FIG. 7. It is also assumed that the information “1” is written in the memory cell 10 in the control information storage unit 45 belonging to the row block 25-0.

When a read command RC is issued in reading data, the read word line WLR0 is initially selected to start the read operation. After the data read is completed, serial read commands are continuously issued.

When the (64n+1)th serial read command (n=0, 1, 2, is issued, the pieces of read data are stored in the data registers, and the data in the last place (data on the side closest to an SO terminal) is output from the SO terminal.

Further, the read operation is started to the read word line of the next address of the previously-selected read word line. From the (64n+2)th to (64n+63)th commands, the pieces of data read on the data registers are serially transferred, and the pieces of data are sequentially output from the SO terminal. The pieces of data of the memory cells 10 arrayed in the form of a matrix are continuously read in synchronization with a clock CLK by combining the read command RC and the serial read commands.

Because the address of the selected read word line is controlled by an internal counter, the pieces of data of the row blocks 25-0 to 25-63 including a defective cell are also output in order. However, the data valid signal DV is also output along with the output data SO of the row block 25-0. When the serial read commands are sequentially issued, the pieces of data of the row block 25-1 are output after 64 clocks. When the row block 25-1 does not include any defective cell, the data valid signal DV changes from a low level to a high level to indicate that the output data SO of the row block 25-0 is valid. Therefore, the receiving side receiving the output data SO can determine whether the output data SO is valid or invalid by referring to the data valid signal DV.

### Sixth Embodiment

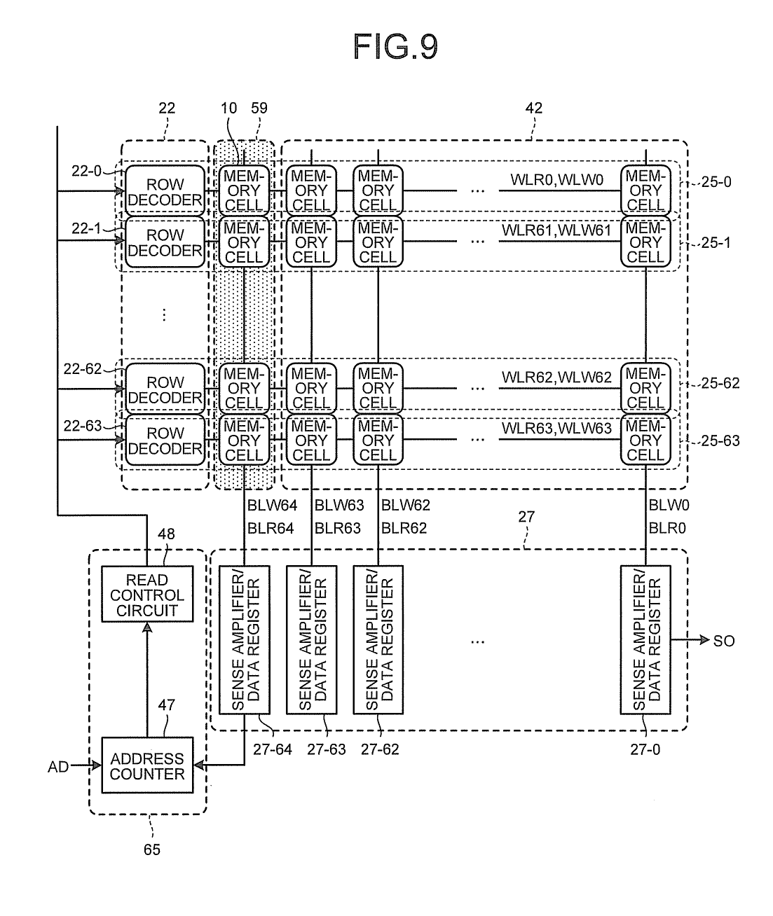

FIG. 9 is a block diagram illustrating a schematic configuration of a nonvolatile semiconductor storage device according to a sixth embodiment.

Referring to FIG. 9, the nonvolatile semiconductor storage device includes a control information storage unit 59 and a skip control circuit 65 instead of the control information storage unit 43 and the data inverting output control circuit 44 of FIG. 5.

The control information storage unit 59 can store whether a memory cell 10 having a small read margin or a memory cell 10 in which data is not correctly read is included in each of the row blocks 25-0 to 25-63 for each row in association with the next row. For example, the memory cell 10 in the control information storage unit 59 of the row block 25-0 can store whether a memory cell 10 having a small read margin or a memory cell 10 in which data is not correctly read is included in the row block 25-1. Similarly, the memory cell 10 in the control information storage unit 59 of the row block 25-1 can store whether a memory cell 10 having a small read margin or a memory cell 10 in which data is not correctly read is included in the row block 25-2. Similarly, the memory cell 10 in the control information storage unit 59 of the row block 25-63 can store whether a memory cell 10 having a small read margin or a memory cell 10 in which data is not correctly read is included in the row block 25-0.

Based on a result of reference to the control information storage unit 59, the skip control circuit 65 can skip reading of data from the memory cells of the next row. Specifically, the skip control circuit 65 includes an address counter 47 and a read control circuit 48.

The address counter 47 can increment the address AD every time output data SO of one row (in the example of FIG. 9, 64 memory cells 10) is output, and increment the address AD based on the result of reference to the control information storage unit 59. The read control circuit 48 can select a row based on a count value AC of the address counter 47.

When data is written in the memory cells 10 in the data storage unit 42, for the row blocks 25-0 to 25-63 in which a memory cell 10 having a small read margin or a memory cell 10 in which data is not correctly read exists, the information “1” is written in the memory cells 10 in the control information storage unit 59 belonging to the row blocks 25-0 to 25-63 that are one row before the relevant row blocks 25-0 to 25-63.

The pieces of data that should be written in the relevant row blocks 25-0 to 25-63 in which a memory cell 10 having a small read margin or a memory cell 10 in which data is not correctly read exists are written in the next row blocks 25-0 to 25-63, and the information “0” is written in the memory cells 10 of the control information storage unit 59 belonging to the row blocks 25-0 to 25-63 that are one row before the relevant row blocks 25-0 to 25-63.

For example, it is assumed that a memory cell 10 having a small read margin or a memory cell 10 in which data is not correctly read exists in the row block 25-2, and that no memory cell 10 having a small read margin or no memory cell 10 in which data is not correctly read exists in the other row blocks 25-0, 25-1, and 25-3 to 25-63.

In such case, the information “1” is written in the memory cell 10 in the control information storage unit 59 belonging to the row block 25-1, the pieces of data that should be written in the row block 25-2 are written in the row block 25-3, and the information “0” is written in the memory cell 10 in the control information storage unit 59 belonging to the row block 25-2. Subsequently, the pieces of data that should be written in the row blocks 25-3 to 25-62 are written in the row blocks 25-4 to 25-63, respectively, that are shifted by one row, and the information “0” is written in the memory cells 10s in the control information storage unit 59 belonging to the row blocks 25-4 to 25-63.

Next, when the pieces of data are read from the row block 25-1, the address AD of the row block 25-1 is output to the read control circuit 48 through the address counter 47, whereby the row decoder 22-1 selects the row block 25-1 to read the pieces of data from the memory cells 10 of the row block 25-1. The pieces of data read from the memory cells 10 in the data storage unit 42 of the row block 25-1 are retained by the sense amplifier/data registers 27-0 to 27-63, respectively. The data read from the memory cell 10 in the control information storage unit 59 of the row block 25-1 is retained by the sense amplifier/data register 27-64. Then, the pieces of data retained by the sense amplifier/data registers 27-0 to 27-63 are output as output data SO, and the data retained by the sense amplifier/data register 27-64 is sent to the address counter 47.

Next, when the pieces of data are read from the row block 25-2, the address AD of the row block 25-2 is input to the address counter 47. At this point, when the data “1” is sent from the sense amplifier/data register 27-64, the address counter 47 increments the address AD of the row block 25-2 to the address of the next row block 25-3. The address AD of the row block 25-3 is output to the read control circuit 48, whereby the row decoder 22-3 selects the row block 25-3 to read the pieces of data from the memory cells 10 of the row block 25-3. The pieces of data read from the memory cells 10 in the data storage unit 42 of the row block 25-3 are retained by the sense amplifier/data registers 27-0 to 27-63, respectively. The data read from the memory cell 10 in the control information storage unit 59 of the row block 25-3 is retained by the sense amplifier/data register 27-64. Then, the pieces of data retained by the sense amplifier/data registers 27-0 to 27-63 are output as output data SO, and the data retained by the sense amplifier/data register 27-64 is sent to the address counter 47.

Next, when the pieces of data is read from the row block 25-4, the address AD of the row block 25-4 is input to the address counter 47. At this point, when the data “0” is sent from the sense amplifier/data register 27-64 to the address counter 47, the address AD of the row block 25-4 is directly output to the read control circuit 48, whereby the row decoder 22-4 selects the row block 25-4 to read the pieces of data from the memory cells 10 of the row block 25-4. The pieces of data read from the memory cells 10 in the data storage unit 42 of the row block 25-4 are retained by the sense amplifier/data registers 27-0 to 27-63, respectively. The data read from the memory cell 10 in the control information storage unit 59 of the row block 25-4 is retained by the sense amplifier/data register 27-64. The pieces of data retained by the sense amplifier/data registers 27-0 to 27-63 are output as output data SO, and the data retained by the sense amplifier/data register 27-64 is sent to the address counter 47.

By writing whether a defective cell is included in the row in the control information storage unit 59 while shifting by one row, a determination whether or not a defective cell is included in the row whose pieces of data are read next can be made when the pieces of data in the row one row before the row including a defective cell are read. Therefore, the row including a defective cell can be skipped, so that the pieces of data can be read from the next row to prevent outputting of invalidated output data SO.

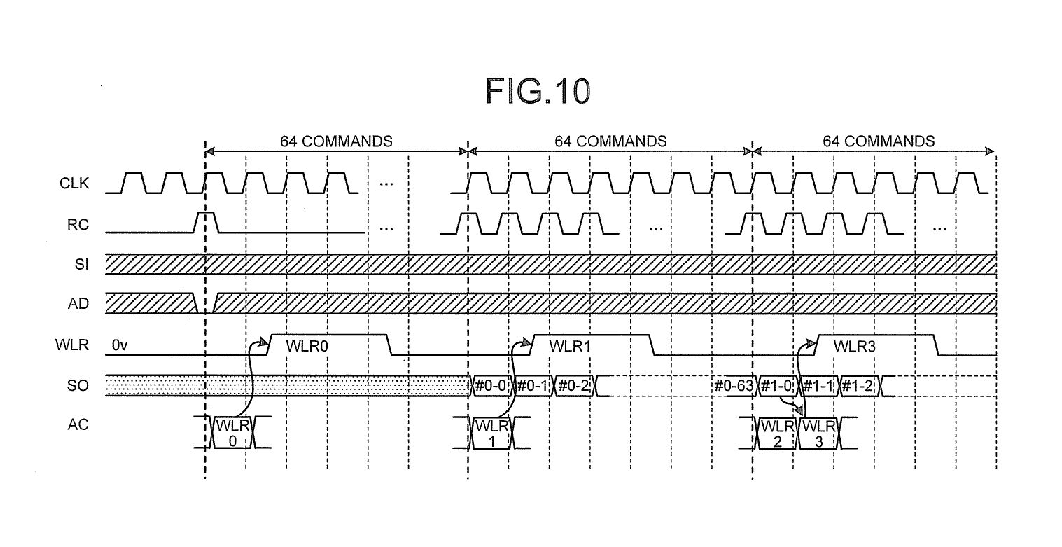

FIG. 10 is a timing chart illustrating waveforms of the respective units of the nonvolatile semiconductor storage device of FIG. 9.

In FIG. 10, the address of an initially-selected read word line is determined by the address AD. The address AD is captured by an initial read command RC to select the row block 25-0 in this example. When the next serial read command is issued, the row address of the read word line is controlled by the address counter 47, and the address signal AC is incremented to select the row block 25-1. Subsequently, the address AD is incremented in every 64 commands.

It is assumed that a defective cell exists in the row block 25-2. In such case, when the serial read commands are issued, the pieces of data in the row block 25-1 are read, and the pieces of read data are stored in the data registers when the 65th serial read command is issued.

The address counter 47 and the read control circuit 48 determine that the pieces of data of the next row block 25-2 is invalid by referring to the data that is read from the control information storage unit 59 in reading the data of the row block 25-1, and the address AD is incremented to the address of the second next row block 25-3. In this manner, because reading of the data from the row block 25-2 having a defective cell can be skipped, the output data SO can be output to outside without interruption.

### Seventh Embodiment

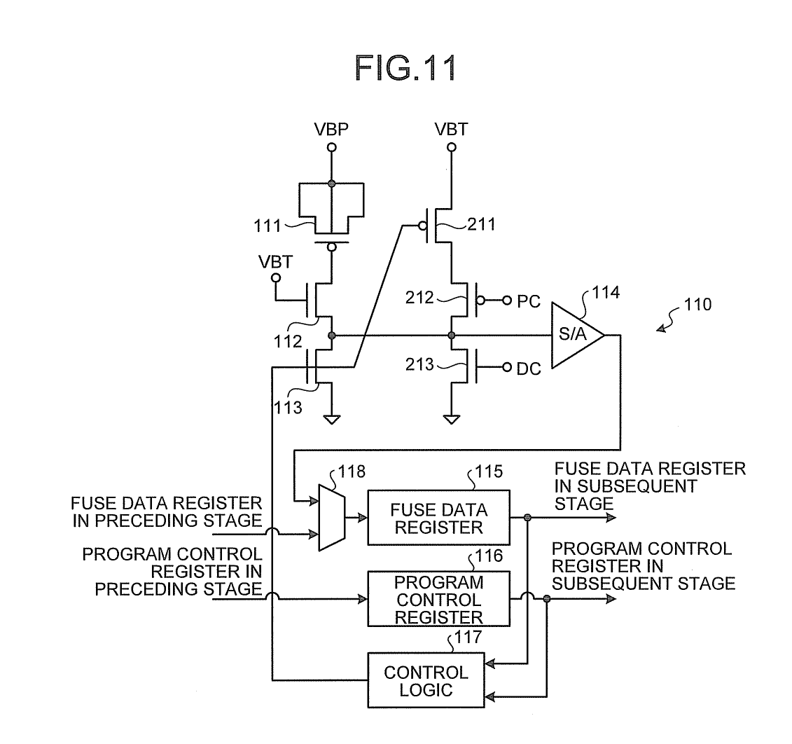

FIG. 11 is a block diagram illustrating a schematic configuration of a nonvolatile semiconductor storage device according to a seventh embodiment.

Referring to FIG. 11, a nonvolatile semiconductor storage device 110 includes a fuse element 111, a barrier transistor 112, a selection transistor 113, a sense amplifier 114, a fuse data register 115, a program control register 116, a control logic 117, and a selector 118. The nonvolatile semiconductor storage device 110 also includes a selection transistor 211, a charge transistor 212, and a discharge transistor 213, to form a charge-discharge path of an input terminal of the sense amplifier 114.

The fuse element 111 can be formed using a MOS transistor, and a source, a drain, and a well of the MOS transistor are commonly connected. The barrier transistor 112 can protect the sense amplifier 114 from voltage that breaks a gate oxide film of the fuse element 111. The selection transistor 113 can select the fuse element 111 in which the gate oxide film of the MOS transistor is broken. The sense amplifier 114 can read data stored in the fuse element 111. The fuse data register 115 can store the data read from the fuse element 111. The program control register 116 can store program control information for performing control during programming. The control logic 117 can control the operation of the selection transistor 113 during the programming. The selector 118 can select the data of the fuse element 111 read by the sense amplifier 114 or the data stored in the preceding fuse data register, and output the selected data to the fuse data register 115 thereof. The selection transistor 211 can form a charge path of the input terminal of the sense amplifier 114 connected to the programmed fuse element 111. The charge transistor 212 can charge the input terminal of the sense amplifier 114 connected to the unselected fuse element 111 during the programming time. The discharge transistor 213 can discharge the input terminal of the sense amplifier 114 before the data of the fuse element 111 is read.

The gate of the MOS transistor of the fuse element 111 is connected to the drain of the barrier transistor 112. The source of the barrier transistor 112 is connected to the drain of the selection transistor 113, the drain of the charge transistor 212, the drain of the discharge transistor 213, and the input terminal of the sense amplifier 114. The output terminal of the sense amplifier 114 is connected to one of input terminals of the selector 118, and the other input terminal of the selector 118 is connected to the output terminal of the preceding fuse data register. The output terminal of the selector 118 is connected to the input terminal of the fuse data register 115, and the output terminal of the fuse data register 115 is connected to the input terminal of the subsequent fuse data register and one of input terminals of the control logic 117. The input terminal of the program control register 116 is connected to the preceding program control register, the output terminal of the program control register 116 is connected to the input terminal of the preceding program control register and the other input terminal of the control logic 117, and the output terminal of the control logic 117 is connected to the gates of the selection transistors 113 and 211. The source of the charge transistor 212 is connected to the source of the selection transistor 211.

The fuse element 111 retains the data “0” before the gate oxide film of the MOS transistor of the fuse element 111 is broken. When the data “1” is written in the fuse element 111, the program control information is transferred to the program control register 116 thereof through the serially-connected program control register.

The program voltage VBP is applied onto the substrate side of the fuse element 111 while the barrier voltage VET is applied to the gate of the barrier transistor 112. At this point, the gate side of the fuse element 111 is previously charged at a potential to a degree to which the gate oxide film of the MOS transistor of the fuse element 111 is not broken.

The control logic 117 determines the timing at which the programming operation is performed by itself based on the data of the fuse element 111 retained by the fuse data register 115 or the program control information retained by the program control register 116. In performing the programming, the control logic 117 sets the potential at the gate of the selection transistor 113 to a high level to turn on the selection transistor 113, thereby reducing the potential at the gate of the fuse element 111 to a low potential VSS. As a result, a high voltage to a degree to which the gate oxide film is broken is applied to the gate oxide film of the MOS transistor of the fuse element 111, and the data “1” is written in the fuse element 111 by the breakdown of the gate oxide film.

When the data “1” is written in the fuse element 111, the selection transistor 113 is turned off to stop the application of the high voltage to the fuse element 111.

During the programming time, in the unselected fuse element 111, the control voltage PC becomes a low level and the charge transistor 212 is turned on, whereby the input terminal of the sense amplifier 114 is maintained at the barrier voltage VBT.

Next, when the data is read from the fuse element 111, the program voltage VBP and the barrier voltage VBT are set to voltages suitable for reading data. For example, the program voltage VBP is set to the power supply voltage VDD, and the barrier voltage VBT is set to about double the power supply voltage VDD. The discharge transistor 213 is turned on by the rise of the control signal DC, and the input terminal of the sense amplifier 114 becomes a standby state for a given time after the input terminal is once discharged so as to become the low potential VSS. The potential at the input terminal of the sense amplifier 114 is maintained at the low potential VSS, when the data “0” is written in the fuse element 111 while the input terminal of the sense amplifier 114 in the standby state. On the other hand, when the data “1” is written in the fuse element 111, charge is accumulated in the input terminal of the sense amplifier 114 through the broken gate oxide film of the fuse element 111 to raise the potential at the input terminal of the sense amplifier 114. The sense amplifier 114 determines whether the data of the fuse element 111 is “0” or “1” from the potential difference of the input terminal of the sense amplifier 114, and latches the data of determination result.

The data latched in the sense amplifier 114 is transferred to the fuse data register 115 and then transferred to the outside through a serially-connected register chain. A fuse macro block is formed by serially connecting the nonvolatile semiconductor storage devices 110 in a plurality of stages.

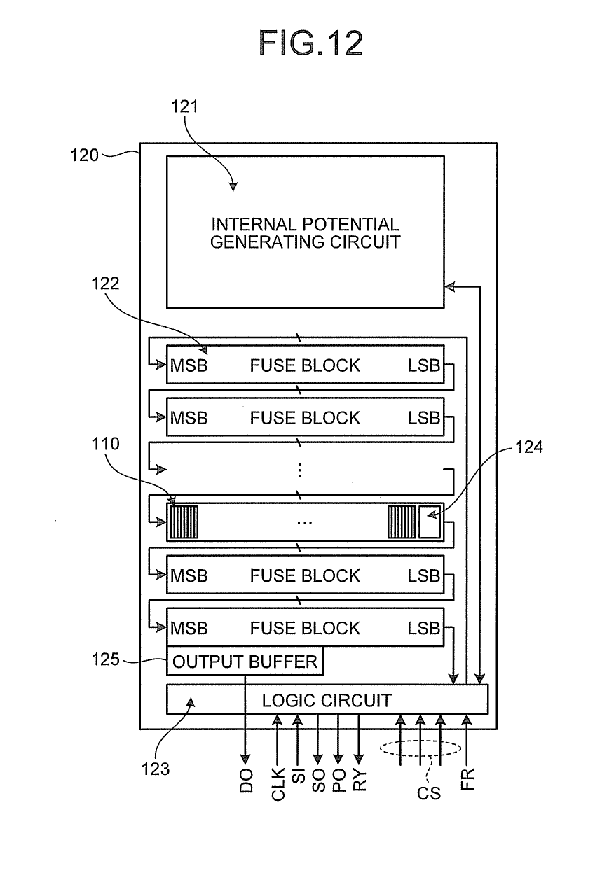

FIG. 12 is a block diagram illustrating a schematic configuration of a fuse macro block that is formed using the nonvolatile semiconductor storage devices of FIG. 11.

Referring to FIG. 12, a fuse macro block 120 includes an internal potential generating circuit 121, fuse blocks 122, a logic circuit 123, and an output buffer 125, and the fuse block 122 includes the nonvolatile semiconductor storage devices 110 and a control logic 124.

The internal potential generating circuit 121 can generate the program voltage VBP applied to the fuse element 111 of FIG. 11 and the barrier voltage VBT applied to the barrier transistor 112 of FIG. 11. The fuse block 122 is formed by serially connecting the nonvolatile semiconductor storage devices 110 of FIG. 11, and the control logic 124 to control the nonvolatile semiconductor storage devices 110 is provided in the fuse block 122. For example, in each of the fuse blocks 122, the nonvolatile semiconductor storage devices 110 for 8 bits are serially connected to form a data memory block, and 16 data memory blocks are serially connected to form a register chain of 8×16=128 bits.

The logic circuit 123 can serially input program data SI to the fuse block 122 in synchronization with a clock signal CLK, and the logic circuit 123 can serially output output data SO read from the fuse block 122. The logic circuit 123 can control writing and reading of the nonvolatile semiconductor storage devices 110 based on a control signal CS. The logic circuit 123 can input a reset signal FR initializing the fuse macro block 120, output a ready signal RY notifying that it is ready for reading, and output a blow signal PO indicating that programming is completed during the programming. The output buffer 125 can output 64-bit output data DO in parallel.

In the fuse macro block 120, the sense amplifier 114 and the control logic 117 of FIG. 11 are provided in each nonvolatile semiconductor storage device 110, so that design of the storage device that operates stably on a wide-range condition can be facilitated.

Also in the fuse macro block 120, by inverting data before output for a bit determined to be defective, the defective cell can be repaired in units of bits without providing any repair cell.

### Eighth Embodiment

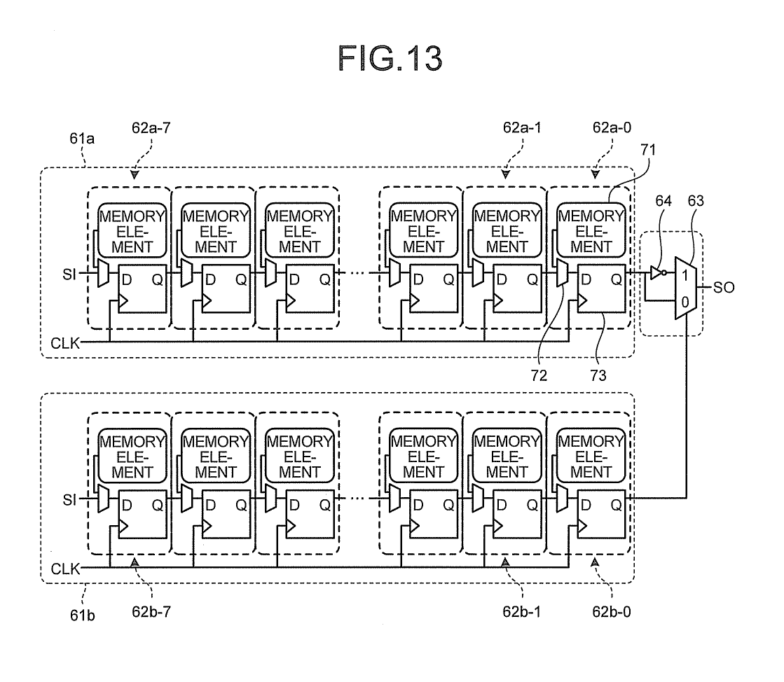

FIG. 13 is a block diagram illustrating a schematic configuration of a nonvolatile semiconductor storage device according to an eighth embodiment.

Referring to FIG. 13, the nonvolatile semiconductor storage device includes a data memory block 61a, an inverted-bit storage memory block 61b, a selector 63, and an inverter 64.

The data memory block 61a includes memory cells 62a-0 to 62a-7, and the memory cells 62a-0 to 62a-7 are serially connected. One-bit data can be stored in each of the memory cells 62a-0 to 62a-7.

The inverted-bit storage memory block 61b includes memory cells 62b-0 to 62b-7 in association with the memory cell 62a-0 to 62a-7, and the memory cells 62b-0 to 62b-7 are serially connected. The memory cells 62b-0 to 62b-7 can store whether or not the memory cells 62a-0 to 62a-7 are defective, respectively. For example, the data “1” can be stored in the memory cell 62b-0 when the memory cell 62a-0 is defective, and the data “0” can be stored in the memory cell 62b-0 when the memory cell 62a-0 is nondefective. Similarly, the data “1” can be stored in the memory cell 62b-1 when the memory cell 62a-1 is defective, and the data “0” can be stored in the memory cell 62b-1 when the memory cell 62a-1 is nondefective.

Each of the memory cells 62a-0 to 62a-7 and 62b-0 to 62b-7 includes a memory element 71, a selector 72, and a fuse data register 73. The memory element 71 can be used as the fuse element 111, the barrier transistor 112, the selection transistor 113, and the sense amplifier 114 of FIG. 11. The selector 72 can be used as the selector 118 of FIG. 11. The fuse data register 73 can be used as the fuse data register 115 of FIG. 11.

In the example of FIG. 13, the method for providing the memory cells 62a-0 to 62a-7 of 8 bits in the data memory block 61a. However, the invention is not limited to the method.

The inverter 64 can invert the data output from the data memory block 61a. Based on the data output from the inverted-bit storage memory block 61b, the selector 63 can select the data output from the data memory block 61a or the data obtained by inverting the data output from the data memory block 61a.

When data is read from the data memory block 61a, pieces of data stored in the memory cells 62a-0 to 62a-7 are continuously read in synchronization with the clock CLK, and pieces of data stored in the memory cells 62b-0 to 62b-7 are continuously read in synchronization with the clock CLK.

For example, the data stored in the memory cell 62b-0 is read when the data stored in the memory cell 62a-0 is read, and the data stored in the memory cell 62b-1 is read when the data stored in the memory cell 62a-1 is read.

The data read from the data memory block 61a is input to one of the input terminals of the selector 63 after being inverted by the inverter 64, and also input to the other input terminal of the selector 63 without being inverted.

When the data “1” is input to the switching terminal from the inverted-bit storage memory block 61b, the selector 63 selects the data obtained by inverting the data read from the data memory block 61a, and the selected data is output as the output data SO. On the other hand, when the data “0” is input to the switching terminal from the inverted-bit storage memory block 61b, the selector 63 selects the data read from the data memory block 61a, and the selected data is output as the output data SO.

Therefore, even if a plurality of defective cells exist, the defective cells can be repaired in units of bits without replacing the defective cells, and data can be serially read without interruption.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A nonvolatile semiconductor storage device comprising:
a first memory cell in which a first fuse element is provided, data being able to be electrically written only once in the first fuse element; and
a second memory cell in which a second fuse element is provided to repair a defect of the first memory cell, data being able to be electrically written only once in the second fuse element.

2. A nonvolatile semiconductor storage device comprising:
a memory cell in which a fuse element is provided, data being able to be electrically written only once in the fuse element; and
a repair controller that inverts data read from the memory cell based on a result of reference to defective bit information indicating whether or not the memory cell is defective and outputs the inverted data.

3. The nonvolatile semiconductor storage device of claim 2, wherein the defective bit information is an address of a defective cell.

4. The nonvolatile semiconductor storage device of claim 3, wherein the repair controller includes an input control circuit that prohibits data from being written in a memory cell specified by the address of the defective cell.

5. The nonvolatile semiconductor storage device of claim 3, wherein the repair controller includes an output control circuit that inverts data read from a memory cell specified by the address of the defective cell and outputs the inverted data.

6. A nonvolatile semiconductor storage device comprising:
a memory cell array in which memory cells are arrayed in a form of a matrix in a row direction and a column direction, data being able to be electrically written only once in the memory cells;
a control information storage unit that stores storage states of memory cells in the same row; and
a control circuit that controls reading of data from the memory cells in the same row based on a result of reference to the control information storage unit.

7. The nonvolatile semiconductor storage device of claim 6, wherein the control information storage unit stores whether inverted data or non-inverted data is written in memory cells in the same row for each row, and
the control circuit includes a data inverting output control circuit that inverts data read from memory cells in the same row and outputs the inverted data based on the result of reference to the control information storage unit.

8. The nonvolatile semiconductor storage device of claim 7, wherein the control information storage unit includes a memory cell in each row to store whether or not inverted data or non-inverted data is written in memory cells in the same row.

9. The nonvolatile semiconductor storage device of claim 8, further comprising:
a row decoder block that selects a row of memory cells included in the memory cell array and a memory cell included in the control information storage unit; and
a sense amplifier block that detects data stored in memory cells included in the memory cell array and data stored in a memory cell included in the control information storage unit in each column.

10. The nonvolatile semiconductor storage device of claim 7, wherein, when the number of memory cells in which data is written in each row block exceeds a half of the number of memory cells provided in each row block, inverted write data is written in the memory cells for the row block in the memory cell array.

11. The nonvolatile semiconductor storage device of claim 10, wherein, when the number of memory cells in which data is written in each row block exceeds a half of the number of memory cells provided in each row block, information “0” remains written in a memory cell that is instructed to write information “1” therein, and information “1” is written in a memory cell that is instructed to write information “0” therein for the row block in the memory cell array.

12. The nonvolatile semiconductor storage device of claim 10, further comprising:
a row decoder block that selects a row of memory cells included in the memory cell array and a memory cell included in the control information storage unit; and
a sense amplifier block that detects data stored in memory cells included in the memory cell array and data stored in a memory cell included in the control information storage unit in each column.

13. The nonvolatile semiconductor storage device of claim 6, wherein the control information storage unit stores whether a memory cell in which data is already written exists in a row block, and
the control circuit includes a re-write preventing circuit that prevents data from being re-written in the memory cell in which the data is already written based on the result of reference to the control information storage unit.

14. The nonvolatile semiconductor storage device of claim 13, wherein the control information storage unit includes a memory cell in each row to store whether a memory cell in which data is already written exists in a row block.

15. The nonvolatile semiconductor storage device of claim 6, wherein the control information storage unit stores whether a defect exists in memory cells in the same row for each row, and
the control circuit includes an invalid output control circuit that invalidates data read from memory cells in the same row based on the result of reference to the control information storage unit.

16. The nonvolatile semiconductor storage device of claim 15, wherein the control information storage unit includes a memory cell in each row to store whether or not a defect exists in memory cells in the same row.

17. The nonvolatile semiconductor storage device of claim 6, wherein the control information storage unit stores whether or not a defect exists in the memory cells in the same row in association with a subsequent row, and
the control circuit includes a skip control circuit that skips reading of data from memory cells in the next row based on the result of reference to the control information storage unit.

18. The nonvolatile semiconductor storage device of claim 17, wherein the control information storage unit includes a memory cell in each row to store whether a defect exists in memory cells in the same row in association with a subsequent row.

19. The nonvolatile semiconductor storage device of claim 2, further comprising:
a data memory block in which the memory cells are serially connected; and
an inverted-bit storage memory block in which memory cells that stores whether or not the memory cells in the data memory block are defective are serially connected.

20. The nonvolatile semiconductor storage device of claim 2, further comprising:
a write transistor that writes data in the fuse element;
a read transistor that reads data from the fuse element;
a write control transistor that is connected in series between the fuse element and the write transistor; and
a read barrier transistor that is connected in series between the fuse element and the read transistor.
